(19) United States
(12) Patent Application Publication
(10) Pub. No.: US 2013/0093464 A1
(43) Pub. Date: Apr. 18, 2013

(54) SIGNAL TRANSFER CIRCUIT

(71) Applicant: Young-Kyu NOH, Gyeonggi-do (KR)

(72) Inventor: Young-Kyu NOH, Gyeonggi-do (KR)

(21) Appl. No.: 13/334,007

(22) Filed: Dec. 21, 2011

(30) Foreign Application Priority Data
Oct. 18, 2011 (KR) 10-2011-0106426

(51) Int. Cl. H03K 19/0175; H03K 17/00; H03K 17/687

(52) U.S. Cl. 326/82; 327/437; 327/365

(57) ABSTRACT

A signal transfer circuit includes a signal transfer unit configured to transfer an input signal applied to an input node to an output node in response to a control signal and a driving unit configured to drive an output signal of the output node to a level of the input signal in response to the control signal.

### CROSS-REFERENCE TO RELATED APPLICATIONS

The present application claims priority of Korean Patent Application No. 10-2011-0106426, filed on Oct. 18, 2011, which is incorporated herein by reference in its entirety.

### BACKGROUND

1. Field

Exemplary embodiments of the present invention relate to a signal transfer circuit, and more particular, to a flip-flop circuit.

2. Description of the Related Art

A CMOS pass gate includes an NMOS transistor and a PMOS transistor and delivers/transfers a signal (or a voltage), which is applied to an input node, or blocks the delivery of the signal depending on the level of a signal input to gates of the NMOS transistor and the PMOS transistor.

FIG. 1 is a diagram illustrating a CMOS pass gate.

As illustrated in FIG. 1, the CMOS pass gate includes an NMOS transistor 110 and a PMOS transistor 120. Hereinafter, the operation of the CMOS pass gate will be described with reference to FIG. 1.

One end of the NMOS transistor 110 and one end of the PMOS transistor 120 are coupled to each other and serve as an input node IN of the CMOS pass gate, and the other end of the NMOS transistor 110 and the other end of the PMOS transistor 120 are coupled to each other and serve as an output node OUT of the CMOS pass gate. The NMOS transistor 110 receives a control signal CON through a gate thereof and the PMOS transistor 120 receives an inverted control signal CONB through a gate thereof. The inverted control signal CONB is obtained by inverting the control signal CON.

When the control signal CON is at a logic ‘high’ level and the inverted control signal CONB is at a logic ‘low’ level, since the NMOS transistor 110 and the PMOS transistor 120 are turned on and thus a current flows between the input node IN and the output node OUT, a signal applied to the input node IN is delivered to the output node OUT. Meanwhile, when the control signal CON is at a logic ‘low’ level and the inverted control signal CONB is at a logic ‘high’ level, since the NMOS transistor 110 and the PMOS transistor 120 are turned off and thus a current does not flow between the input node IN and the output node OUT, no signal applied to the input node IN is delivered to the output node OUT.

FIG. 2 is a waveform diagram illustrating the features of the CMOS pass gate.

Hereinafter, the physical characteristics of the CMOS pass gate will be described with reference to FIG. 2.

As illustrated in FIG. 2, a clock signal may be used as the control signal CON of the CMOS pass gate. In such a case, the CMOS pass gate delivers the signal of an input terminal IN to an output terminal OUT in a logic ‘high’ level period of the clock signal and does not deliver the signal of the input terminal IN to the output terminal OUT in a logic ‘low’ level period of the clock signal.

If a signal output to the output terminal OUT is at a ‘low’ level and a signal applied to the input terminal IN transitions from a ‘low’ level to a ‘high’ level, the signal output to the output terminal OUT starts to transition from a logic ‘low’ level to a logic ‘high’ level from a time point of the rising edge 201 of the control signal CON.

In further detail, the NMOS transistor 110 and the PMOS transistor 120 operate as follows.

The input terminal IN corresponds to the drains of the NMOS transistor 110 and the PMOS transistor 120, and the output terminal OUT corresponds to the sources of the NMOS transistor 110 and the PMOS transistor 120. When the control signal CON reaches a logic ‘high’ level, the amplitude of a gate-source voltage of the NMOS transistor 110 is larger than an absolute value of a threshold voltage, and the NMOS transistor 110 is turned on. At this time, since the inverted control signal CONB is at a logic ‘low’ level and the amplitude of a gate-source voltage of the PMOS transistor 120 is smaller than the absolute value of the threshold voltage, the PMOS transistor 120 is not turned on. The NMOS transistor 110 and the PMOS transistor 120 are turned on, when the amplitude of the gate-source voltages thereof is larger than the absolute value of the threshold voltage, and are turned off, when the amplitude of the gate-source voltages thereof is smaller than the absolute value of the threshold voltage.

When a current flows from the input node IN to the output node OUT by the NMOS transistor 110, the level of a signal output to the output node OUT is gradually increased. When the level of the signal output to the output node OUT is increased and the amplitude of the gate-source voltage of the PMOS transistor 120 is larger than the absolute value of the threshold voltage, the PMOS transistor 120 is turned on. When the current continuously flows and the level of the signal output to the output node OUT approximates to a logic ‘high’ level, the amplitude of the gate-source voltage of the NMOS transistor 110 is smaller than the absolute value of the threshold voltage, and the NMOS transistor 110 is turned off. In the period until the NMOS transistor 110 is turned off after the PMOS transistor 120 is turned on, a current flows from the input node IN to the output node OUT by the NMOS transistor 110 and the PMOS transistor 120. After the NMOS transistor 110 is turned off, a current flows from the input node IN to the output node OUT by the turned-on PMOS transistor 120.

That is, when the level of the signal output to the output node OUT approximates to a logic ‘low’ level, a current mainly flows by the NMOS transistor 110. When the level of the signal output to the output node OUT is gradually increased and approximates to a logic ‘high’ level, a current mainly flows by the PMOS transistor 120. However, since the channel mobility of the PMOS transistor 120 is lower than that of the NMOS transistor 110, when the NMOS transistor 110 and the PMOS transistor 120 have substantially the same size, the PMOS transistor 120 does not allow a current to easily flow as compared with the NMOS transistor 110 (in order to allow a current to easily flow, the size of a transistor is to be increased). Specifically, when the level of the signal output to the output node OUT approximates to a logic ‘high’ level, since a difference between voltages (drain-source voltages of the transistors 110 and 120) of the input terminal IN and the output node OUT is also reduced, the amount of a current flowing from the input node IN to the output node OUT is reduced more and more.

Therefore, the waveform of the signal output to the output node OUT may be distorted (202) as illustrated in FIG. 2, and the time taken for the level of the signal output to the output node OUT to transition may be increased. When the frequency of a clock signal with which an integrated circuit operates is increased and the waveform of a signal is distorted or the transition time of the signal is increased in a high frequency operation as described above, an error may occur in the operation of the integrated circuit.

### SUMMARY

Exemplary embodiments of the present invention are directed to a signal transfer circuit capable of accurately operating in a high frequency by reducing a transition time of a single output to an output node.

In accordance with an exemplary embodiment of the present invention, a signal transfer circuit includes a signal transfer unit configured to transfer an input signal applied to an input node to an output node in response to a control signal, and a driving unit configured to drive an output signal of the output node to a level of the input signal in response to the control signal.

The driving unit may include a pull-up driving section that pulls up the output node when the signal applied to the input node is at a high level in the period in which the control signal has been activated.

The driving unit may include a pull-down driving section that pulls down the output node when the signal applied to the input node is at a low level in the period in which the control signal has been activated.

In accordance with another exemplary embodiment of the present invention, a flip-flop circuit includes a first pass gate configured to transfer an input signal applied to an input node to a first internal node in response to a control signal, a driving unit configured to drive a first signal of the first internal node to a level of the input signal in response to the control signal, and a signal output unit configured to store the first signal of the first internal node and invert the first signal of the first internal node to output an inverted signal to an output node in response to the control signal.

In accordance with further exemplary embodiment of the present invention, a signal transfer circuit includes a signal transfer unit configured to transfer an input signal applied to an input node to an output node in response to a control signal, and a driving unit configured to supply the output node with a voltage for a voltage level of the input signal in response to the input signal and the control signal.

### BRIEF DESCRIPTION OF THE DRAWINGS

FIG. 1 is a diagram illustrating a CMOS pass gate.

FIG. 2 is a waveform diagram illustrating the features of a CMOS pass gate.

FIG. 3A and FIG. 3B are a diagram showing a signal transfer circuit in accordance with an exemplary embodiment of the present invention.

FIG. 4 is a waveform diagram illustrating the operation of a signal transfer circuit illustrated in FIGS. 3A and 3B.

FIG. 5 is a diagram illustrating a flip-flop circuit in accordance with an exemplary embodiment of the present invention.

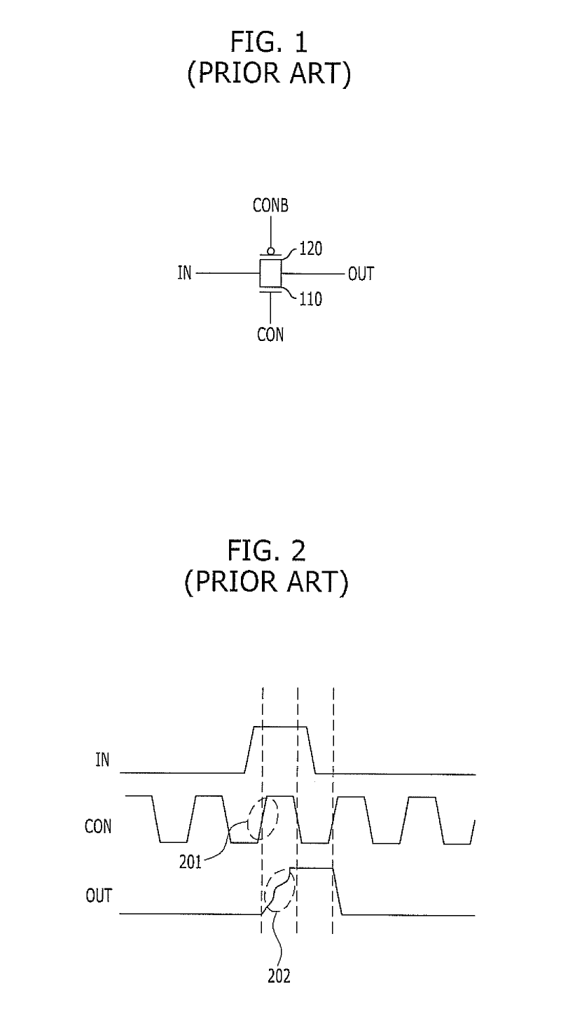

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

Hereinafter, a signal applied to a specific node or a signal of a specific node represents a signal with a logic value determined by a voltage level of the specific node. Signals in the exemplary embodiments of the present invention may have a logic ‘high’ level or a logic ‘low’ level when they are activated. Furthermore, a level of a signal corresponds to a logic value of the signal. The logic ‘high’ level of the signal represents that the logic value of the signal is ‘high’, and the logic ‘low’ level of the signal represents that the logic value of the signal is ‘low’.

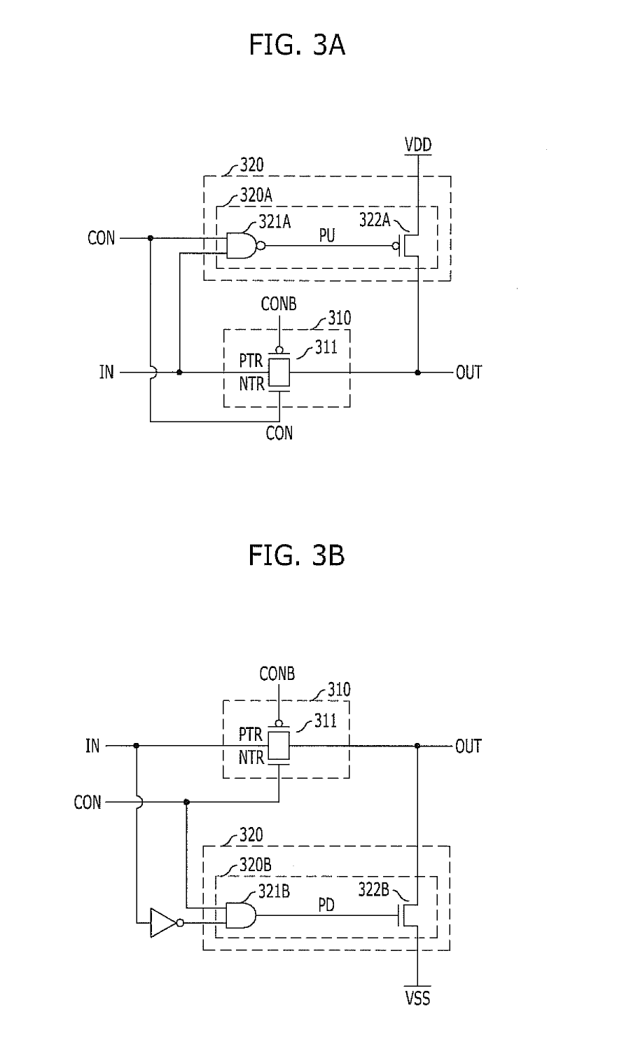

FIGS. 3A and 3B are a configuration diagram of a signal delivery/transfer circuit in accordance with an exemplary embodiment of the present invention. FIG. 3A illustrates the signal transfer circuit including a pull-up driving section 320A as a driving unit 320, and FIG. 3B illustrates the signal transfer circuit including a pull-down driving section 320B as the driving unit 320.

As illustrated in FIGS. 3A and 3B, the signal transfer circuit includes a signal transfer unit 310 and the driving unit 320. The signal transfer unit 310 is configured to transfer a signal applied to an input node IN to an output node OUT in the period in which a control signal CON has been activated. The driving unit 320 is configured to drive the signal (or voltage) level of the output node OUT to the level of the signal applied to the input node IN in the period in which the control signal CON has been activated. The signal transfer unit 310 may be a pass gate 311 including an NMOS transistor NTR and a PMOS transistor PTR. The signal transfer unit 310 may be any circuit that transfers the signal applied to the input node IN to the output node OUT in response to a logic value of the control signal CON. Accordingly, the signal delivery unit 310 may not be the pass gate. Hereinafter, an inverted control signal CONB represents a signal obtained by inverting the control signal CON. It will be described below as an example that the activation level of the control signal CON is ‘high’.

The operation of the signal transfer circuit when the driving unit 320 includes only the pull-up driving section 320A will be described with reference to FIG. 3A.

When the control signal CON is activated, the signal transfer unit 310 transfers a signal (hereinafter, referred to as an input signal IN) applied to the input node IN as a signal (hereinafter, referred to as an output signal OUT) output to the output node OUT. Hereinafter, the signal delivery unit 310 will be described as the pass gate 311, for example. The pass gate 311 transfers the input signal IN as the output signal OUT, when the control signal CON is at a logic ‘high’ level, and does not transfer the input signal IN as the output signal OUT when the control signal CON is at a logic ‘low’ level.

When the input signal IN is at a logic ‘high’ level in the activation period of the control signal CON, the pull-up driving section 320A pulls up the output signal OUT to the logic ‘high’ level which is the level of the input signal IN. Thus, the output signal OUT is pulled-up by a current flowing between the output node OUT and the input node IN and the pull-up driving section 320A and quickly transitions from a logic ‘low’ level to a logic ‘high’ level (in case that the output signal OUT is at a logic ‘low’ level before the input signal IN is transferred).

For such an operation, the pull-up driving section 320A may include a pull-up signal generation part 321A and a pull-up part 322A. The pull-up signal generation part 321A is configured to activate (an activation level is a logic ‘low’ level) a pull-up signal PU when the input signal IN is at the logic ‘high’ level in the period in which the control signal CON has been activated. The pull-up part 322A is configured to pull up the output node OUT in the period in which the pull-up signal PU has been activated. As illustrated in FIG. 3A, the pull-up signal generation part 321A may include an NAND gate which is configured to receive the control signal CON and the input signal IN and output the pull-up signal PU. The pull-up part 322A may include a PMOS transistor having a source to which a power supply voltage VDD of a logic ‘high’ level is applied, a drain coupled to the output node OUT, and a gate to which the pull-up signal PU is input.

The operation of the signal transfer circuit when the driving unit 320 includes only the pull-down driving section 320B will be described with reference to FIG. 3B.

The operation of the signal transfer unit 310 is substantially the same as the description of FIG. 3A.

When the input signal IN is at a logic ‘low’ level in the activation period of the control signal CON, the pull-down driving section 320B pulls down the output signal OUT to the logic ‘low’ level which is the level of the input signal IN. Thus, the output signal OUT is pulled-down by a current flowing between the output node OUT and the input node IN and the pull-down driving section 320B and quickly transitions from a logic ‘high’ level to a logic ‘low’ level (in case that the output signal OUT is at a logic ‘high’ level before the input signal IN is transferred).

For such an operation, the pull-down driving section 320B may include a pull-down signal generation part 321B and a pull-down part 322B. The pull-down signal generation part 321B is configured to activate (an activation level is a ‘high’ logic level) a pull-down signal PD when the input signal IN is at the ‘low’ logic level in the period in which the control signal CON has been activated. The pull-down part 322B is configured to pull down the output node OUT in the period in which the pull-down signal PD has been activated. As illustrated in FIG. 3B, the pull-down signal generation part 321B may include an AND gate which is configured to receive the control signal CON and an inverted signal of the input signal IN and output the pull-down signal PD. The pull-down part 322B may include an NMOS transistor having a source to which a ground voltage VSS of a ‘low’ logic level is applied, a drain coupled to the output node OUT, and a gate to which the pull-down signal PD is input.

The driving unit 320 may include only the pull-up driving section 320A as illustrated in FIG. 3A, only the pull-down driving section 320B as illustrated in FIG. 3B, or both the pull-up driving section 320A and the pull-down driving section 320B. When the driving unit 320 includes both the pull-up driving section 320A and the pull-down driving section 320B, the configuration and coupling state of the pull-up driving section 320A are substantially the same as those illustrated in FIG. 3A, and the configuration and coupling state of the pull-down driving section 320B are substantially the same as those illustrated in FIG. 3B.

In the case that the driving unit 320 includes only the pull-up driving section 320A, the output signal OUT transitions from a logic ‘low’ level to a logic ‘high’ level quickly and accurately as compared with the conventional art. In the case that the driving unit 320 includes only the pull-down driving section 320B, the output signal OUT transitions from a logic ‘high’ level to a logic ‘low’ level quickly and accurately as compared with the conventional art. In the case that the driving unit 320 includes both the pull-up driving section 320A and the pull-down driving section 320B, the output signal OUT transitions quickly and accurately similarly to the above two cases. When the output signal OUT transitions quickly and accurately, a signal transfer circuit may easily operate even in an integrated circuit operating with a high frequency.

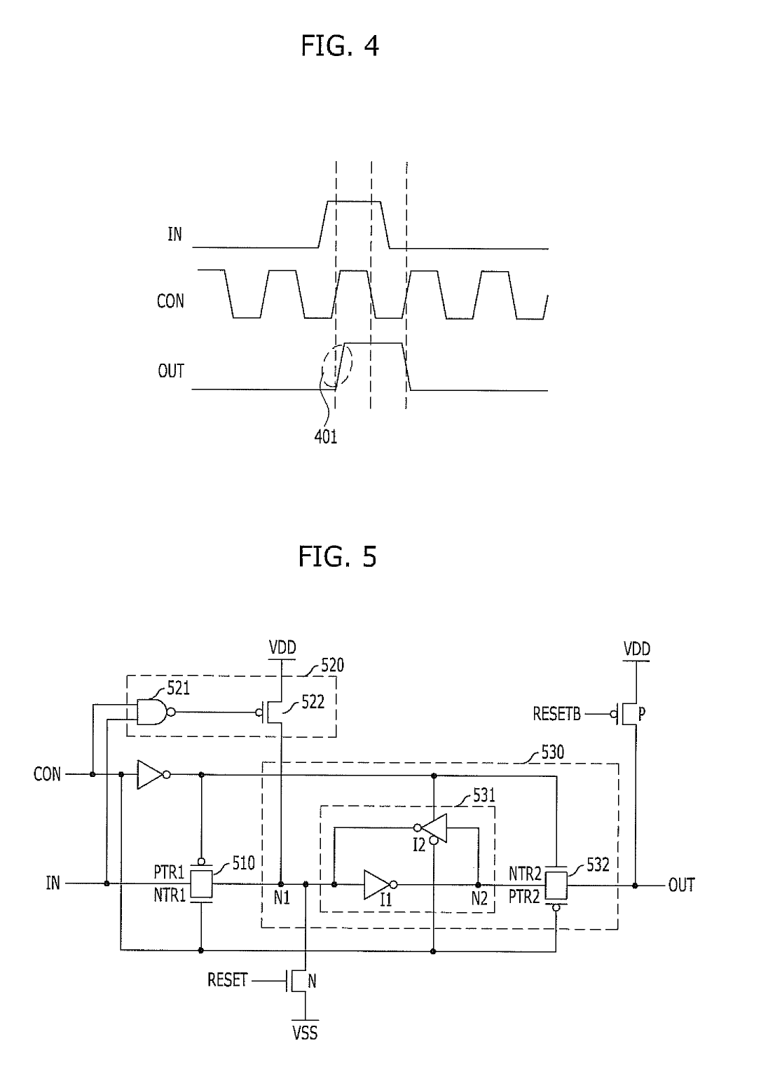

FIG. 4 is a waveform diagram illustrating the operation of the signal transfer circuit illustrated in FIG. 3A.

As described in FIG. 2, when the input signal IN transitions from the logic ‘low’ level to the logic ‘high’ level, the output signal OUT of the logic ‘low’ level also transitions from the logic ‘low’ level to the logic ‘high’ level in the activation period of the control signal CON. The pull-up driving section 320A pulls up the output node OUT by allowing a current to flow between the power supply voltage VDD and the output node OUT. In this way, the output signal OUT may be prevented from being distorted (401) when the level of the output signal OUT approximates to a logic ‘high’ level and the pass gate 311 does not allow a current to easily flow, thereby compensating for an insufficient margin in a high frequency operation.

FIG. 5 is a configuration diagram of a flip-flop circuit in accordance with the embodiment of the present invention. The flip-flop circuit illustrated in FIG. 5 stores one bit of data (or signal) and is a D-flip-flop circuit configured to delay a signal applied to the input node IN by a set delay value and output a delayed signal to the output node OUT.

As illustrated in FIG. 5, the flip-flop circuit includes a first pass gate 510, a driving unit 520, and a signal output unit 530. The first pass gate 510 is configured to transfer the signal applied to the input node IN to a first internal node N1 in the period in which the control signal CON has been activated. The driving unit 520 is configured to drive the signal (or voltage) level of the first internal node N1 to the level of the signal applied to the input node IN in the period in which the control signal CON has been activated. The signal output unit 530 is configured to store the signal of the first internal node N1 and invert the signal of the first internal node N1 to output an inverted signal to the output node OUT in the period in which the control signal CON has been deactivated.

The driving unit 520 illustrated in FIG. 5 includes only the pull-up driving section 320A similarly to the driving unit 320 illustrated in FIG. 3A. However, the driving unit 520 may also include only the pull-down driving section 320B similarly to the driving unit 320 illustrated in FIG. 3B or both the pull-up driving section 320A and the pull-down driving section 320B.

The configuration and operation of the first pass gate 510 and the driving unit 520 are substantially the same as those of the signal transfer circuit described in FIG. 3A (or the signal transfer circuit described in FIG. 3B when the driving unit 520 includes the pull-down driving section 320B). The first pass gate 510 transfers the input signal IN to the first internal node N1 or blocks the transfer of the input signal IN in response to the control signal CON, and the driving unit 520 pulls up the first internal node N1 to a logic ‘high’ level when the input signal IN is at a logic ‘high’ level in the period in which the control signal CON has been activated (a logic ‘high’ level). The driving unit 520 includes a pull-up signal generation section 521 and a pull-up section 522.

The signal output unit 530 stores the signal of the first internal node N1 when the input signal IN is transferred to the first internal node N1 in the period in which the control signal CON has been activated and inverts the signal of the first internal node N1 to transfer an inverted signal as the output signal OUT in the period in which the control signal CON has been deactivated.

For such an operation, the signal output unit 530 includes a storage section 531 and a second pass gate 532. The storage section 531 is configured to invert the signal of the first internal node N1 to transfer the inverted signal to a second internal node N2 and store the signal of the first internal node N1 in the period in which the control signal CON has been deactivated. The second pass gate 532 is configured to transfer a signal of the second internal node N2 to the output node OUT in the period in which the control signal CON has been deactivated.

The signal of the first internal node N1 is inverted by a first inverter I1, regardless of whether the control signal CON is activated, and is transferred to the second internal node N2. Since a second inverter I2 is activated only when the control signal CON is deactivated, the storage section 531 operates like a latch only when the control signal CON is deactivated.

Since signals applied to the gates of an NMOS transistor NTR2 and a PMOS transistor PTR2 included in the second pass gate 532 have logic values opposite those of signals applied to the gates of an NMOS transistor NTR1 and a PMOS transistor PTR1 included in the first pass gate 510, respectively, the second pass gate 532 transfers the signal of the second internal node N2 to the output node OUT in the period in which the control signal CON has been deactivated (the logic ‘low’ level) and does not transfer the signal of the second internal node N2 to the output node OUT in the period in which the control signal CON has been activated (the logic ‘high’ level).

The signal transfer circuit described in FIGS. 3A and 3B may be applied to the second pass gate 532 in the same manner. That is, the driving unit 320 may be coupled to the second pass gate 532 in a similar manner as illustrated in FIGS. 3A and 3B. The driving unit 320 is coupled thereto, so that the output node OUT may be pulled up to a ‘high’ logic level when the second pass gate 532 transfers the signal of the second internal node N2, which has a ‘high’ logic level, to the output node OUT (the operation of the pull-up driving section 320A), and the output node OUT may be pulled down to a ‘low’ logic level when the second pass gate 532 transfers the signal of the second internal node N2, which has a ‘low’ logic level, to the output node OUT (the operation of the pull-down driving section 320B).

A first reset transistor N is turned on when a reset signal RESET is activated (a logic ‘high’ level) and initializes the first internal node N1 at the ground voltage VSS of a logic ‘low’ level. A second reset transistor P is turned on when an inverted reset signal RESETB (obtained by inverting the reset signal RESET) is activated and initializes the output node OUT at the power supply voltage VDD of a logic ‘high’ level.

In accordance with the flip-flop circuit according to the present invention, the signal of the first internal node N1 and the output signal OUT are less distorted, and the output signal OUT transitions quickly and accurately, so that the flip-flop circuit may easily operate even in an integrated circuit operating with a high frequency.

In accordance with the signal transfer circuit according to the present invention, a time taken for a signal output to an output node to transition may be reduced without increasing the size of a transistor, so that the signal transfer circuit may accurately operate even in a high frequency.

While the present invention has been described with respect to the specific embodiments, it will be apparent to those skilled in the art that various changes and modifications may be made without departing from the spirit and scope of the invention as defined in the following claims.

What is claimed is:

1. A signal transfer circuit comprising:
a signal transfer unit configured to transfer an input signal applied to an input node to an output node in response to a control signal; and
a driving unit configured to drive an output signal of the output node to a level of the input signal in response to the control signal.

2. The signal transfer circuit of claim 1, wherein:
the signal transfer unit is configured to transfer the input signal to the output node when the control signal is activated; and
the driving unit is configured to supply the output node with a voltage having the same voltage level as the input signal when the control signal is activated.

3. The signal transfer circuit of claim 1, wherein the signal transfer unit includes a pass gate having an NMOS transistor and a PMOS transistor.

4. The signal transfer circuit of claim 1, wherein the driving unit comprises:
a pull-up driving section configured to pull up the output node when the input signal is at a logic high level in a period in which the control signal is activated.

5. The signal transfer circuit of claim 1, wherein the driving unit comprises:
a pull-down driving section configured to pull down the output node when the input signal is at a logic low level in a period in which the control signal is activated.

6. The signal transfer circuit of claim 1, wherein the driving unit comprises:
a pull-up driving section configured to pull up the output node when the input signal is at a logic high level in a period in which the control signal is activated; and
a pull-down driving section configured to pull down the output node when the input signal is at a logic low level in the period in which the control signal is activated.

7. The signal transfer circuit of claim 4, wherein the pull-up driving section comprises:
a pull-up signal generation part configured to activate a pull-up signal when the input signal is at the logic high level in the period in which the control signal is activated; and
a pull-up part configured to pull up the output node in a period in which the pull-up signal is activated.

8. The signal transfer circuit of claim 5, wherein the pull-down driving section comprises:
a pull-down signal generation part configured to activate a pull-down signal when the input signal is at the logic low level in the period in which the control signal is activated; and
a pull-down part configured to pull down the output node in a period in which the pull-down signal is activated.

9. A flip-flop circuit comprising:
a first pass gate configured to transfer an input signal applied to an input node to a first internal node in response to a control signal;
a driving unit configured to drive a first signal of the first internal node to a level of the input signal in response to the control signal; and
a signal output unit configured to store the first signal of the first internal node and invert the first signal of the first internal node to output an inverted signal to an output node in response to the control signal.

10. The flip-flop circuit of claim 9, wherein:
the first pass gate is configured to transfer the input signal to the first internal node when the control signal is activated;
the driving unit is configured to supply the first internal node with a voltage having the same voltage level as the input signal when the control signal is activated; and
the signal output unit configured to store the first signal of the first internal node and output the inverted signal to the output node when the control signal is deactivated.

11. The flip-flop circuit of claim 9, wherein the driving unit comprises:
a pull-up driving section configured to pull up the first internal node when the input signal is at a logic high level in a period in which the control signal is activated.

12. The flip-flop circuit of claim 9, wherein the driving unit comprises:
a pull-down driving section configured to pull down the first internal node when the input signal is at a logic low level in a period in which the control signal is activated.

13. The flip-flop circuit of claim 9, wherein the driving unit comprises:
a pull-up driving section configured to pull up the first internal node when the input signal is at a logic high level in a period in which the control signal is activated; and
a pull-down driving section configured to pull down the first internal node when the input signal is at a logic low level in a period in which the control signal is activated.

14. The flip-flop circuit of claim 9, wherein the signal output unit comprises:
a storage unit configured to invert the first signal of the first internal node to transfer an inverted signal to a second internal node, wherein the storage unit is configured to store the first signal of the first internal node in a period in which the control signal is deactivated; and
a second pass gate configured to transfer a second signal of the second internal node to the output node in the period in which the control signal is deactivated.

15. A signal transfer circuit comprising:
a signal transfer unit configured to transfer an input signal applied to an input node to an output node in response to a control signal; and
a driving unit configured to supply the output node with a voltage for a voltage level of the input signal in response to the input signal and the control signal.

16. The signal transfer circuit of claim 15, wherein, in a period in which the control signal is activated, the driving unit is configured to supply the output node with a power supply voltage, when the input signal has a logic high level, and a ground voltage when the input signal has a logic low level.
